(19) United States
(12) Patent Application Publication
(10) Pub. No.: US 2011/0223744 A1
(43) Pub. Date: Sep. 15, 2011

(54) METHOD FOR MANUFACTURING AN OPTICAL SEMICONDUCTOR DEVICE AND COMPOSITION FOR FORMING A PROTECTIVE LAYER OF AN OPTICAL SEMICONDUCTOR DEVICE

(75) Inventors: Yohei NOBE, Tokyo (JP); Hitoshi Kato, Tokyo (JP); Kunpei Kobayashi, Tokyo (JP); Koji Sumiya, Tokyo (JP); Chiaki Miyamoto, Tokyo (JP); Terukazu Kokubo, Tokyo (JP)

(73) Assignee: JSR CORPORATION, Tokyo (JP)

(21) Appl. No.: 12/892,193

(22) Filed: Sep. 28, 2010

(30) Foreign Application Priority Data
Sep. 29, 2009 (JP) 2009-223669
Aug. 26, 2010 (JP) 2010-189838

(51) Int. Cl. H01L 21/78; C08L 83/04

(52) U.S. Cl. 438/462; 524/588; 257/E21.599

(57) ABSTRACT

Provided is a composition for forming a protective layer which has an excellent acid resistance, an excellent cracking resistance and does not adversely affect semiconductor layers even when acid is used to remove deposits that arise during formation of separation trenches for separating a substrate into device units. Also provided is a method for manufacturing an optical semiconductor device using such a composition. The composition for forming a protective layer includes a siloxane polymer and an organic solvent. The method for manufacturing an optical semiconductor device includes the steps of: forming a protective layer 4 by coating a surface of semiconductor layers 2 and 3 formed on a substrate 1 with a composition for forming a protective layer; forming separation trenches 6 by irradiating the protective layer 4 from above with a laser; and removing deposits that arise during formation of the separation trenches 6.

### BACKGROUND OF THE INVENTION

1. Field of the Invention

The present invention relates to a method for manufacturing an optical semiconductor device and to a composition for forming a protective layer of an optical semiconductor device.

2. Description of the Related Art

Techniques for forming a protective layer (i.e. a protective film) prior to forming separation trenches by laser in the course of optical semiconductor device fabrication are known.

As an example of such a technique, Japanese Patent Application Laid-open No. 2004-31526 discloses a method for manufacturing group III nitride compound semiconductor devices in which group III nitride compound semiconductor devices that have been formed on a substrate are separated into individual devices. The method disclosed in this document includes a semiconductor layer removing step wherein a group III nitride compound semiconductor layer on a separation line is placed in a state where only an electrode forming layer on a side close to the substrate remains or is placed in a state where there is no group III nitride compound semiconductor layer on a separation line, a protective layer forming step that forms a protective layer which covers layers on the substrate surface side and can be removed in a subsequent step, a laser scanning step that scans a laser beam along the separation line and forms separation trenches and a protective layer removing step that removes the protective film and unwanted substances that arise due to laser beam scanning, wherein the substrate is separated into individual devices using the separation trenches formed by scanning a laser beam along the separation lines, thereby forming individual group III nitride compound semiconductor devices.

The method described in the foregoing document prevents molten matter or the like that arises due to laser scanning from adhering to the semiconductor device by forming a protective layer. In addition, this method prevents cracking and loss of material defects from occurring in the optical semiconductor device by laser scanning.

### SUMMARY OF THE INVENTION

Deposits such as molten matter that arises during formation of the separation trenches can be removed with, for example, acid. In such cases, it is desirable for the protective layer that has been formed on the surface of the semiconductor layer to have a high resistance for acid (i.e. a high acid resistance). It is also desirable for the protective layer to have an excellent resistance to cracking. The reason is as follows. If cracks were to arise, the acid would penetrate into the cracks to cause the semiconductor layer below the protective layer to incur adverse effects.

Hence, there exists a desire for a protective layer which is endowed with both an excellent acid resistance and an excellent resistance to cracking. However, Japanese Patent Application Laid-open No. 2004-31526 makes no mention whatsoever of specific examples of protective layer materials. The inventors investigated protective layer materials. However, the inventors were unable to find in the existing literature any materials capable of forming a protective layer having both an excellent acid resistance and an excellent resistance to cracking.

It is therefore one object of the present invention to provide a composition for forming a protective layer which has both an excellent acid resistance and an excellent cracking resistance and which, even when an acid is used to remove deposits that arise during the formation of separation trenches for separation into device units, does not have an adverse influence on the semiconductor layers. Another object of the invention is to provide a method for manufacturing an optical semiconductor device using such a composition.

The inventors have discovered that the above objects can be achieved by using a specific material to form a protective layer.

Accordingly, the invention provides the following [1] to [10].

[1] A method for manufacturing an optical semiconductor device having a substrate and a semiconductor layer formed on the substrate, wherein the method includes; a protective layer forming step of forming a protective layer by coating a surface of the semiconductor layer formed on the substrate with a composition for forming a protective layer; a separation trench forming step of forming one or more separation trenches that are deeper than a sum of the thickness of the protective layer and the thickness of the semiconductor layer by irradiating the protective layer from above with a laser; and a deposit removing step of removing deposits that arise during formation of the separation trenches, and wherein the composition for forming a protective layer includes a siloxane polymer and an organic solvent.

[2] The method for manufacturing an optical semiconductor device according to [1], further including a protective layer removing step of removing the protective layer after the deposit removing step.

[3] The method for manufacturing an optical semiconductor device according to [1] or [2], further including, as a final step, a substrate separating step of separating the substrate into device units at the one or more separation trenches.

[4] The method for manufacturing an optical semiconductor device according to any one of [1] to [3], further including, prior to the protective layer forming step, a recess forming step of forming, in a region of the semiconductor layer that includes a position where the separation trenches are to be formed, a recess which is shallower than the separation trenches so as to have a broader width than the separation trench.

[5] The method for manufacturing an optical semiconductor device according to any one of [1] to [4], wherein the siloxane polymer is a hydrolytic condensate obtained by hydrolytic condensation of a silane compound containing at least one type selected from the group consisting of:

compounds represented by general formula (1) below

R¹_{c}SiX¹_{4-c} (1),

wherein R¹ is a monovalent non-hydrolyzable group, X¹ is a monovalent hydrolyzable group, and the letter c is an integer from 0 to 2;

compounds represented by general formula (2) below

R²_{b}(X²)_{3-b}Si—R⁴—Si(X³)_{3-c}R³_{c} (2),

wherein R² and R³ are the same or different and each is independently a monovalent non-hydrolyzable group, R⁴ is a divalent non-hydrolyzable group, X² and X³ are the same or different and each is independently a monovalent hydrolyzable group, and the letters b and c are the same or different and each is independently an integer from 0 to 2; and

hydrolyzable polycarbosilanes.

[6] The method for manufacturing an optical semiconductor device according to any one of [1] to [5], wherein the siloxane polymer has a weight-average molecular weight of from 1,000 to 30,000.

[7] The method for manufacturing an optical semiconductor device according to any one of [1] to [6], wherein the composition for forming a protective layer includes from 0.001 to 10 parts by mass of an alkaline metal compound or an alkaline earth metal compound per 100 parts by mass of the siloxane polymer.

[8] The method for manufacturing an optical semiconductor device according to any one of [1] to [7], wherein the composition for forming a protective layer includes silica particles.

[9] A composition for forming a protective layer of an optical semiconductor device for forming a protective layer formed temporarily on a surface of a semiconductor layer in the course of optical semiconductor device fabrication, wherein the composition includes a siloxane compound and an organic solvent.

[10] The composition for forming a protective layer of an optical semiconductor device according to [9], wherein the siloxane polymer is a hydrolytic condensate obtained by hydrolytic condensation of a silane compound containing at least one type selected from the group consisting of:

compounds represented by general formula (1) below

R¹_{c}SiX¹_{4-c} (1),

wherein R¹ is a monovalent non-hydrolyzable group, X¹ is a monovalent hydrolyzable group, and the letter c is an integer from 0 to 2;

compounds represented by general formula (2) below)

R²_{b}(X²)_{3-b}Si—R⁴—Si(X³)_{3-c}R³_{c} (2),

wherein R² and R³ are the same or different and each is independently a monovalent non-hydrolyzable group, R⁴ is a divalent non-hydrolyzable group, X² and X³ are the same or different and each is independently a monovalent hydrolyzable group, and the letters b and c are the same or different and each is independently an integer from 0 to 2; and

hydrolyzable polycarbosilanes.

One advantage of the present invention is that, because a specific material is used to form a protective layer, even when acid is used to remove deposits that arise during the formation of separation trenches for separating the substrate into device units, the acid does not have an adverse effect on the semiconductor layer.

Another advantage of the invention is that, because deposits that arise during the formation of separation trenches are removed, electrical shorts do not arise between the various regions (e.g., p electrode layers and n electrode layers) that make up the optical semiconductor device. For this reason, a highly reliable optical semiconductor device can be manufactured.

A further advantage of the invention is that, because a laser is used, cracking and loss of material defects do not arise when the optical semiconductor device is separated into device units.

### BRIEF DESCRIPTION OF THE DRAWINGS

FIG. 1 is a flow chart showing an example of the method of the present invention for manufacturing an optical semiconductor device.

### DESCRIPTION OF THE PREFERRED EMBODIMENTS

The method of the present invention for manufacturing an optical semiconductor device includes the steps of a protective layer forming step (B) forming a protective layer by coating a surface of a semiconductor layer that has been formed on a substrate with a composition for forming a protective layer; a separation trench forming step (C) forming one or more separation trenches that are deeper than a sum of the thicknesses of the protective layer and the semiconductor layer by irradiating the protective layer from above with a laser; and a deposit removing step (D) removing deposits that arise during formation of the separation trenches.

The method of the present invention for manufacturing an optical semiconductor device may include, prior to the protective layer forming step (B), the step of a recess forming step (A) forming, in a region of the semiconductor layer that includes a position where the separation trenches are to be formed, a recess which has a broader width and is shallower than the separation trenches.

The method of the present invention for manufacturing an optical semiconductor device may include, after the deposit removing step (D), the step of a protective layer removing step (E) removing the protective layer.

The method of the present invention for manufacturing an optical semiconductor device may include, as the final step, the step of a substrate separating step (F) separating the substrate into device units at the one or more separation trenches.

An embodiment of the optical semiconductor device are described below in conjunction with the appended diagrams.

As used herein, “optical semiconductor device” (sometimes abbreviated below as “semiconductor device”) is a concept that encompasses both devices having one semiconductor layer and devices having two or more semiconductor layers.

Moreover, in this specification, reference to an optical semiconductor device shall be understood to include the substrate, protective layer and other elements formed in the vicinity of the semiconductor layer.

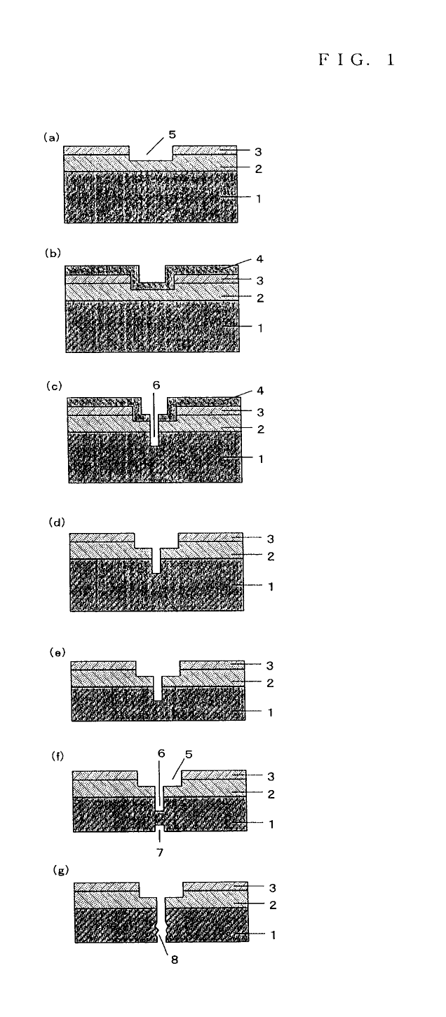

As shown in FIG. 1(c), an optical semiconductor device has a semiconductor layer, which is a stack composed of a substrate 1, an n electrode layer 2 and a p electrode layer 3, and also has a protective layer 4 which has been formed to protect the semiconductor layer. The optical semiconductor device also has a separation trench 6 having a depth that reaches at least the substrate 1, and a recess 5 (see FIG. 1(a)) which is formed in a surface region that includes a position where the separation trench 6 is formed and which has a broader width and is shallower than the separation trench 6.

The protective layer 4 is formed along the top side (i.e. the upper surface) of the p electrode layer 3, the side walls (i.e. the side surfaces) of the n electrode layer 2 and the p electrode layer 3 in the recess 5, and the surfaces of the top side of the n electrode in the recess 5 other than the places where the separation trench 6 has been formed, and is provided for the purpose of protecting the semiconductor layer from the acid used in the subsequently described a deposit removing step (step D).

An embodiment of the method of the present invention for manufacture which includes steps A to F is described below in conjunction with the appended diagrams.

### Step A; Recess Forming Step

As shown in FIG. 1(a), first, a recess 5 is formed downward from the top side of a semiconductor layer (specifically, a stack which includes an n electrode layer 2 and a p electrode layer 3) on a substrate 1, in a surface region of the semiconductor layer which includes the position where a separation trench 6 is to be formed. The recess 5 is formed so as to have a broader width and be shallower than the separation trench 6. Also, the recess 5 is formed so as to have a shallower depth than the thickness of the semiconductor layer.

Illustrative examples of the optical semiconductor device at which the method of the present invention is directed include group III nitride compound semiconductor devices in which GaN, InGaN or the like is used as the constituent material (e.g., blue LEDs).

Illustrative examples of the material of substrate 1 include silicon, sapphire, spinel and silicon carbide.

Although the semiconductor layer may actually include layers other than an n electrode layer 2 and a p electrode layer 3, an n electrode layer 2 and a p electrode layer 3 are illustrated here as two typical examples of the various places where electrical shorts must not be allowed to arise; the mention of other layers is omitted here.

Formation of the recess 5 may be carried out by etching, by dicing with a dicer, or by the like.

### Step B; Protective Layer Forming Step

Next, as shown in FIG. 1(b), a composition for forming a protective layer is coated onto the surface of the semiconductor layer (i.e. stack composed of n electrode layer 2 and p electrode layer 3, etc.; sometimes referred to in this specification as semiconductor layers 2 and 3) that was formed on the substrate 1 and is heated, thereby forming a protective layer 4. The protective layer 4 is provided in order to protect the semiconductor layer from acid used in the subsequently described a deposit removing step (step D). Coating techniques such as spin coating, dipping, roll coating or spraying may be employed as the method of application. Two or more compositions may be used as the composition for forming a protective layer. In such a case, it is possible to mix and apply the two or more compositions together, or to first apply and heat one composition and subsequently apply and heat the other composition.

The protective layer 4 that has been formed has a film thickness of preferably from 0.6 to 1.5 and more preferably from 0.7 to 1.2 μm. At a film thickness of less than 0.6 μm, the acid resistance may be inadequate.

The temperature during heating is preferably from 100 to 800° C., and more preferably from 300 to 700° C.

The composition for forming a protective layer is described more fully below.

The composition for forming a protective layer used in the present invention includes a siloxane polymer and an organic solvent.

### A. Siloxane Polymer

“Siloxane polymer” refers herein to a hydrolytic condensate obtained by the hydrolytic condensation of a silane compound containing at least one type selected from the group consisting of (a) compounds of general formula (1) (also referred to below as “Silane Compound 1”), (b) compounds of general formula (2) below (also referred to below as “Silane Compound 2”), and (c) hydrolyzable polycarbosilanes.

In this invention, —Si—O—Si— bonds can be formed by hydrolytic condensation between silane compounds.

### (a) Silane Compound 1

Silane Compound 1 is a compound of general formula (1) below:

R¹_{c}SiX¹_{4-c} (1)

In the general formula (1), R¹ is a monovalent non-hydrolyzable group, X¹ is a monovalent hydrolyzable group, and the letter c is an integer from 0 to 2.

The monovalent non-hydrolyzable group represented by R¹ is exemplified by hydrocarbon groups having 1 to 10 carbons and halogenated hydrocarbon groups having 1 to 10 carbons.

The monovalent hydrolyzable group represented by X¹ is exemplified by a hydrogen atom, a halogen atom, a monovalent alkoxy group having 1 to 10 carbons and a monovalent acyloxy group having 1 to 10 carbons.

In the general formula (1), the hydrocarbon group having 1 to 10 carbons represented by R¹ is exemplified by monovalent linear or branched hydrocarbon groups having 1 to 10 carbons, monovalent alicyclic hydrocarbon groups having 3 to 10 carbons and monovalent aromatic hydrocarbon groups having 6 to 10 carbons.

The above monovalent linear or branched hydrocarbon group having 1 to 10 carbons is preferably a monovalent linear or branched hydrocarbon group having 1 to 4 carbons.

The “hydrocarbon group” in the monovalent linear or branched hydrocarbon group having 1 to 10 carbons is exemplified by alkyl groups, alkenyl groups and alkynyl groups. Preferred examples of the above alkyl group include methyl, ethyl, isopropyl, n-propyl and tert-butyl. Preferred examples of the above alkenyl group include vinyl and allyl. Preferred examples of the above alkynyl group include ethynyl and propargyl.

The above monovalent alicyclic hydrocarbon group having 3 to 10 carbons is more preferably a monovalent alicyclic hydrocarbon group having 3 to 8 carbons. Specific examples of “alicyclic hydrocarbon groups” include cycloalkyl groups such as cyclopropyl, cyclobutyl, cyclopentyl and cyclohexyl; and cycloalkenyl groups such as cyclobutenyl, cyclopentenyl and cyclohexenyl. The bonding site of the above alicyclic hydrocarbon group may be on any carbon atom on the aliphatic ring.

The above monovalent aromatic hydrocarbon group having 6 to 10 carbons is exemplified by phenyl groups and alkylphenyl groups.

In the general formula (1), halogenated hydrocarbon groups having 1 to 10 carbons represented by R¹ are exemplified by groups in which some or all of the hydrogen atoms on the above hydrocarbon group have been substituted with halogen atoms such as fluorine atoms or the like.

Examples of the halogen atoms represented by X¹ include chlorine atoms and bromine atoms. Preferred examples of the alkoxy groups having 1 to 10 carbons include the alkoxy groups having 1 to 4 carbons. Specific examples of the alkoxy groups having 1 to 4 carbons include methoxy, ethoxy, n-propoxy, isopropoxy and n-butoxy. Preferred examples of the acyloxy groups having 1 to 10 carbons include acyloxy groups having 1 to 4 carbons. Specific examples of acyloxy groups having 1 to 4 carbons include acetoxy, propionyloxy and butyryloxy.

Specific examples of Silane Compound 1 include tetramethoxysilane, tetraethoxysilane, tetra-n-propoxysilane, tetraisopropoxysilane, tetra-n-butoxysilane, tetraisobutoxysilane, trimethoxysilane, triethoxysilane, tri-n-propoxysilane, triisopropoxysilane, tri-n-butoxysilane, triisobutoxysilane, methyltrimethoxysilane, methyltriethoxysilane, methyltri-n-propoxysilane, methyltriisopropoxysilane, methyltri-n-butoxysilane, ethyltrimethoxysilane, ethyltriethoxysilane, ethyltri-n-propoxysilane, ethyltriisopropoxysilane, ethyltri-n-butoxysilane, n-propyltrimethoxysilane, n-propyltriethoxysilane, n-propyltri-n-propoxysilane, n-propyltriisopropoxysilane, n-propyltri-n-butoxysilane, isopropyltrimethoxysilane, isopropyltriethoxysilane, isopropyltri-n-propoxysilane, isopropyltriisopropoxysilane, isopropyltri-n-butoxysilane, n-butyltrimethoxysilane, n-butyltriethoxysilane, n-butyltri-n-propoxysilane, n-butyltriisopropoxysilane, n-butyltri-n-butoxysilane, sec-butyltrimethoxysilane, sec-butyltriethoxysilane, sec-butyltri-n-propoxysilane, sec-butyltriisopropoxysilane, sec-butyltri-n-butoxysilane, tert-butyltrimethoxysilane, tert-butyltriethoxysilane, tert-butyltri-n-propoxysilane, tert-butyltriisopropoxysilane, tert-butyltri-n-butoxysilane, phenyltrimethoxysilane, phenyltriethoxysilane, phenyltri-n-propoxysilane, phenyltriisopropoxysilane, phenyltri-n-butoxysilane, dimethyldimethoxysilane, dimethyldiethoxysilane, dimethyldi-n-propoxysilane, dimethyldiisopropoxysilane, dimethyldi-n-butoxysilane, diethyldimethoxysilane, diethyldiethoxysilane, vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, vinyltriphenoxysilane, allyltrimethoxysilane, allyltriethoxysilane, trichlorosilane, methyltrichlorosilane, vinyltrichlorosilane, methyldichlorosilane, dimethyldichlorosilane and dichlorosilane. These may be used singly or as combinations of two or more thereof.

Compounds that are especially preferred as Silane Compound 1 include tetramethoxysilane, tetraethoxysilane, trimethoxysilane, triethoxysilane, methyltrimethoxysilane, methyltriethoxysilane, methyltri-n-propoxysilane, methyltri-iso-propoxysilane, ethyltrimethoxysilane, ethyltriethoxysilane, phenyltrimethoxysilane, phenyltriethoxysilane, dimethyldimethoxysilane, dimethyldiethoxysilane, vinyltrimethoxysilane, vinyltriethoxysilane, trichlorosilane and dichlorosilane. These may be used singly or as combinations of two or more thereof.

When the above Silane Compound 1 is used, the content of Silane Compound 1 is preferably from 5 to 100 mass %, based on a combined amount of Silane Compound 1, Silane Compound 2 and hydrolyzable polycarbosilane which is 100 mass %.

### (b) Silane Compound 2

Silane Compound 2 is a compound represented by the general formula (2) below.

R²_{b}(X²)_{3-b}Si—R⁴—Si(X³)_{3-c}R³_{c} (2),

In the general formula (2), R² and R³ are the same or different and each is independently a monovalent non-hydrolyzable group, R⁴ is a divalent non-hydrolyzable group of 1 to 12 carbons, X² and X³ are the same or different and each is independently a monovalent hydrolyzable group, and the letters b and c are the same or different and each is independently an integer from 0 to 2.

The non-hydrolyzable group represented by R² and R³ is exemplified by hydrocarbon groups having 1 to 10 carbons and halogenated hydrocarbon groups having 1 to 10 carbons.

The divalent hydrocarbon groups having 1 to 12 carbons represented by R⁴ are exemplified by a methylene group, alkylene groups having 2 to 10 carbons and cycloalkylene groups having 3 to 12 carbons.

The hydrolyzable groups represented by X² and X³ are exemplified by hydrogen atoms, halogen atoms, alkoxy groups having 1 to 10 carbons, and acyloxy groups having 1 to 10 carbons.

In above general formula (2), the hydrocarbon groups and halogenated hydrocarbon groups represented by R² and R³ are exemplified by the same groups as R⁴ in above general formula (1). Also, in the above general formula (2), the hydrogen atoms, halogen atoms, alkoxy groups of 1 to 10 carbons and acyloxy groups of 1 to 10 carbons represented by X² and X³ in above general formula (2) are exemplified by the same groups as X⁴ in the above general formula (1).

When the above Silane Compound 2 is used, the content of Silane Compound 2 is preferably from 5 to 100 mass %, based on a combined amount of Silane Compound 1, Silane Compound 2 and hydrolyzable polycarbosilane which is 100 mass %.

Specific examples of Silane Compound 2 include bis(trimethoxysilyl)methane, bis(triethoxysilyl)methane, bis(tri-n-propoxysilyl)methane, bis(tri-iso-propoxysilyl)methane, bis(tri-n-butoxysilyl)methane, bis(tri-sec-butoxysilyl)methane, bis(tri-tert-butoxysilyl)methane, 1-(dimethoxymethylsilyl)-1-(trimethoxysilyl)methane, 1-(diethoxymethylsilyl)-1-(triethoxysilyl)methane, 1-(di-n-propoxymethylsilyl)-1-(tri-n-propoxysilyl)methane, 1-(di-iso-propoxymethylsilyl)-1-(tri-iso-propoxysilyl)methane, 1-(di-n-butoxymethylsilyl)-1-(tri-n-butoxysilyl)methane, 1-(di-sec-butoxymethylsilyl)-1-(tri-sec-butoxysilyl)methane, 1-(di-tert-butoxymethylsilyl)-1-(tri-tert-butoxysilyl)methane, bis(dimethoxymethylsilyl)methane, bis(diethoxymethylsilyl)methane, bis(di-n-propoxymethylsilyl)methane, bis(di-iso-propoxymethylsilyl)methane, bis(di-n-butoxymethylsilyl)methane, bis(di-sec-butoxymethylsilyl)methane and bis(di-tert-butoxymethylsilyl)methane.

Of these, preferred examples include bis(trimethoxysilyl)methane, bis(triethoxysilyl)methane, 1-(dimethoxymethylsilyl)-1-(trimethoxysilyl)methane, 1-(diethoxymethylsilyl)-1-(triethoxysilyl)methane, bis(dimethoxymethylsilyl)methane and bis(diethoxymethylsilyl)methane.

Silane Compound 2 may be used singly or as a combination of two or more thereof.

### (c) Hydrolyzable Polycarbosilane

The hydrolyzable polycarbosilane has on the molecule two or more Si—R—Si bonds (wherein R is a divalent hydrocarbon group) and one or more Si—X bonds (wherein X is a hydrolyzable group such as a hydrogen atom, a halogen atom, an alkoxy group having 1 to 10 carbons or an acyloxy group having 1 to 10 carbons).

The hydrolyzable polycarbosilane is exemplified by dimethoxypolycarbosilanes, diethoxypolycarbosilanes, methylpolycarbosilanes, ethylpolycarbosilanes and dichloropolycarbosilanes. Examples of commercial hydrolyzable polycarbosilanes include Nipusi Type-UH and Nipusi Type-S.

The polystyrene-equivalent weight-average molecular weight of the hydrolyzable polycarbosilane, as determined by gel permeation chromatography (GPC), is preferably from 1,000 to 20,000, and more preferably from 1,000 to 10,000. When the weight-average molecular weight is less than 1,000, problems may arise with the coating properties. On the other hand, when the weight-average molecular weight is more than 20,000, particles have a tendency to form. In addition, the pores within the protective layer that is formed using the resulting hydrolyzed condensate become too large. These are undesirable.

When the above hydrolyzable polycarbosilane is used, the content of the hydrolyzable polycarbosilane is preferably from 5 to 100 mass %, based on a combined amount of Silane Compound 1, Silane Compound 2 and hydrolyzable polycarbosilane which is 100 mass %.

### (d) Catalyst

The catalyst used when obtaining the hydrolyzable condensate is preferably at least one type of compound selected from among metal chelate compounds, acidic compounds and basic compounds, and is more preferably an acidic compound.

(d-1) Metal Chelate Compound

A metal chelate compound that may be used as the catalyst is represented by the general formula (4) below.

R¹⁵ₑM(OR¹⁶)_{f-e} (4)

In the general formula (4), R¹⁵ is a chelating agent, M is a metal atom, R¹⁶ is an alkyl group or an aryl group, the letter f is the valence of the metal M, and the letter e is an integer from 1 to f.

Here, the metal M is preferably at least one metal selected from among group IIIB metals (for example, aluminum, gallium, indium, thallium and the like) and group IVA metals (for example, titanium, zirconium, hafnium and the like), and is more preferably titanium, aluminum and zirconium.

Examples of the chelating agent represented by R¹⁵ include CH₃COCH₂COCH₃ and CH₃COCH₂COOC₂H₅.

The alkyl group or aryl group represented by R¹⁶ is exemplified by the alkyl groups or aryl groups represented by R¹ in the above general formula (1).

Preferred examples of the metal chelating compound include (CH₃(CH₃) HCO)₄₋ₜTi(CH₃COCH₂COCH₃)ₜ, (CH₃(CH₃)HCO)₄₋ₜTi(CH₃COCH₂COOC₂H₅)ₜ, (C₄H₉O)₄₋ₜTi(CH₃COCH₂COCH₃)ₜ, (C₄H₉O)₄₋ₜTi(CH₃COCH₂COOCH₂H₅)ₜ, (C₂H₅(CH₃)HCO)₄₋ₜTi(CH₃COCH₂COCH₃)ₜ, (C₂H₅)(CH₃)HCO)₄₋ₜTi (CH₃COCH₂COOC₂H₅)ₜ, (CH₃(CH₃)HCO)₄₋ₜZr(CH₃COCH₂COCH₃)ₜ, (CH₃(CH₃)HCO)₄₋ₜZr(CH₃COCH₂COOCH₂H₅)ₜ, (C₄H₉O)₄₋ₜZr (CH₃COCH₂COCH₃)ₜ, (C₄H₀O)₄₋ₜZr(CH₃COCH₂COOCH₂H₅)ₜ, (C₂H₅(CH₃)HCO)₄₋ₜZr(CH₃COCH₂COCH₃)ₜ, (C₂H₅(CH₃)HCO)₄₋ₜZr(CH₃COCH₂COOC₂H₅)ₜ, (CH₃(CH₃)HCO)₃₋ₜAl(CH₃COCH₂COCH₃)ₜ, (CH₃(CH₃)HCO)₃₋ₜAl(CH₃COCH₂COOCH₂H₅)ₜ, (C₄H₉O)₃₋ₜAl(CH₃COCH₂COCH₃)ₜ, (C₄H₉O)₃₋ₜAl(CH₃COCH₂COOCH₂H₅)ₜ, (C₂H₅(CH₃)HCO)₃₋ₜAl(CH₃COCH₂COCH₃)ₜ and (C₂H₅(CH₃)HCO)₃₋ₜAl(CH₃COCH₂COOC₂H₅)ₜ. Here, the letter t is an integer from 0 to 4.

The amount of metal chelating compound is preferably from 0.0001 to 10 parts by mass, and more preferably from 0.001 to 5 parts by mass, per 100 parts by mass of the above Silane Compound 1, Silane Compound 2 and hydrolyzable polycarbosilane combined. When the amount is less than 0.0001 part by mass, the film coating properties may worsen. On the other hand, when the amount is more than 10 parts by mass, there may be cases where polymer growth cannot be controlled to give rise to gelation.

When a hydrolyzable silane compound is hydrolytically condensed in the presence of a metal chelating compound, it is preferable to use from 0.5 to 20 moles of water, and especially preferable to use from 1 to 10 moles of water, per mole of Silane Compound 1, Silane Compound 2 and the hydrolyzable polycarbosilane combined. When the amount of water is less than 0.5 mole, the hydrolysis reaction may not fully proceed, and problems with the coating properties and the storage stability sometimes arise. On the other hand, when the amount of water exceeds 20 moles, polymer precipitation or gelation sometimes arises during the hydrolysis and condensation reactions. Also, it is preferable to intermittently or continuously add water.

(d-2) Acidic Compound

Acidic compounds capable of being used as the catalyst are exemplified by organic acids and inorganic acids. Of these, organic acids are preferred.

Illustrative examples of organic acids include acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, shikimic acid, 2-ethylhexanoic acid, oleic acid, stearic acid, linoleic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, tartaric acid, maleic anhydride, itaconic acid, succinic acid, mesaconic acid, citraconic acid, malic acid, glutaric acid hydrolyzate, maleic anhydride hydrolyzate, and fumaric anhydride hydrolyzate.

Illustrative examples of inorganic acids include hydrochloric acid, nitric acid, sulfuric acid, hydrofluoric acid and phosphoric acid.

Of these, to minimize the risk of polymer precipitation or gelation during the hydrolysis and condensation (i.e. hydrolysis followed by condensation) reactions, an organic acid is preferred. Of these, a compound having a carboxyl group is more preferred.

Among compounds having a carboxyl group, an organic acid such as acetic acid, oxalic acid, maleic acid, formic acid, malonic acid, phthalic acid, fumaric acid, itaconic acid, succinic acid, mesaconic acid, citraconic acid, malic acid, malonic acid, glutaric acid or maleic anhydride hydrolyzate is especially preferred.

These acidic compounds may be used singly or as combinations of two or more thereof.

The amount of the acidic compound is preferably from 0.0001 to 10 parts by mass, and more preferably from 0.001 to 5 parts by mass, per 100 parts by mass of Silane Compound 1, Silane Compound 2 and hydrolyzable polycarbosilane combined. When the amount is less than 0.0001 part by mass, the film coating properties may worsen. On the other hand, when the amount is more than 10 parts by mass, there may be cases where the hydrolysis and condensation reactions proceed abruptly to give rise to gelation.

When a hydrolyzable silane compound is hydrolytically condensed in the presence of an acidic compound, it is preferable to use from 0.5 to 20 moles of water, and especially preferable to use from 1 to 10 moles of water, per mole of Silane Compound 1, Silane Compound 2 and the hydrolyzable polycarbosilane combined. When the amount of water is less than 0.5 mole, the hydrolysis reaction may not fully proceed, and problems with the coating properties and the storage stability sometimes arise. On the other hand, when the amount of water exceeds 20 moles, polymer precipitation or gelation sometimes arises during the hydrolysis and condensation reactions. Also, it is preferable to intermittently or continuously add water.

(d-3) Basic Compound

Illustrative examples of basic compounds capable of being used as the catalyst include methanolamine, ethanolamine, propanolamine, butanolamine, N-methylmethanolamine, N-ethylmethanolamine, N-propylmethanolamine, N-butylmethanolamine, N-methylethanolamine, N-ethylethanolamine, N-propylethanolamine, N,N-dimethylmethanolamine, N,N-diethylmethanolamine, N,N-dipropylmethanolamine, N,N-dibutylmethanolamine, N-methyldimethanolamine, N-ethyldimethanolamine, N-propyldimethanolamine, N-butyldimethanolamine, N-(aminomethyl)methanolamine, N-(aminomethyl)ethanolamine, N-(aminomethyl)propanolamine, N-(aminomethyl)butanolamine, methoxymethylamine, methoxyethylamine, methoxypropylamine, methoxybutylamine, N,N-dimethylamine, N,N-diethylamine, N,N-dipropylamine, N,N-dibutylamine, trimethylamine, triethylamine, tripropylamine, tributylamine, tetramethylammonium hydroxide, tetraethylammonium hydroxide, tetrapropylammonium hydroxide, tetrabutylammonium hydroxide, tetramethylethylenediamine, tetraethylethylenediamine, tetrapropylethylenediamine, ammonia, sodium hydroxide, potassium hydroxide, tetramethylammonium hydroxide, tetraethylammonium hydroxide, tetra-n-propylammonium hydroxide, tetra-n-butylammonium hydroxide, tetramethylammonium bromide, tetramethylammonium chloride and tetraethylammonium bromide.

The amount of the acidic compound is preferably from 0.00001 to 10 moles, and more preferably from 0.00005 to 5 moles, per mole of Silane Compound 1, Silane Compound 2 and hydrolyzable polycarbosilane combined.

### (e) Organic Solvent

The organic solvent used when obtaining the hydrolytic condensate included in the composition for forming a protective layer of the invention is exemplified by at least one solvent selected from the group consisting of alcohol solvents, ketone solvents, amide solvents, ether solvents, ester solvents, aliphatic hydrocarbon solvents, aromatic solvents and halogenated solvents.

Of these, the use of alcohol solvents, ketone solvents and ether solvents is preferred. For example, use may be made of alcohol solvents having one hydroxyl group, such as methanol, ethanol, n-propanol, i-propanol, n-butanol, butanol, sec-butanol and t-butanol; polyhydric alcohol solvents having two or more hydroxyl groups, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol; polyhydric alcohol partial ether solvents obtained by the partial etherification of an alcohol having two or more hydroxyl groups, such as ethylene glycol monomethyl ether, ethylene glycol monoethyl ether, ethylene glycol monopropyl ether and ethylene glycol monobutyl ether; ether solvents obtained by the etherification of an alcohol having two hydroxyl groups, such as ethyl ether, i-propyl ether, n-butyl ether, n-hexyl ether, 2-ethyl hexyl ether, ethylene oxide, 1,2-propylene oxide, dioxolane, 4-methyldioxolane, dioxane, dimethyldioxane, ethylene glycol dimethyl ether and ethylene glycol diethyl ether; and ketone solvents such as acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-1-butyl ketone, trimethylnonanone, cyclopentanone, cyclohexanone, cycloheptanone, cyclooctanone, 2-hexanone, methyl cyclohexanone, 2,4-pentanedione, acetonylacetone and diacetone alcohol.

The reaction temperature in the hydrolytic condensation of the hydrolyzable silane compound is preferably from 0 to 100° C., and more preferably from 20 to 80° C. The reaction time is preferably from 30 to 1,000 minutes, and more preferably from 30 to 180 minutes.

### (f) Weight-Average Molecular Weight of Hydrolytic Condensate

The weight-average molecular weight (Mw) of the hydrolytic condensate, expressed as the polystyrene equivalent value obtained by gel permeation chromatography, is preferably from 1,000 to 30,000, more preferably from 1,000 to 15,000, and even more preferably from 1,500 to 5,000. When Mw is less than 1,000, problems may arise with the coating properties or the film uniformity. On the other hand, when Mw is above 30,000, gelation may arise or the acid resistance may decrease.

### B. Organic Solvent

The organic solvent used as an ingredient in the composition for forming a protective layer of the invention may be an organic solvent similar to the organic solvent used to obtain the above-described hydrolytic condensate.

The total solids concentration of the composition for forming a protective layer of the invention, which may be set as appropriate for the intended use, is preferably from 0.1 to 30 mass %. When the concentration is within a range of from 0.1 to 30 mass %, the applied film will have a thickness within a suitable range and will have a better storage stability.

This total solids concentration is adjusted by concentration or by dilution with an organic solvent if necessary.

The composition for forming a protective layer may include an alkaline metal compound or an alkaline earth metal compound. Including such a compound has the effect of increasing the acid resistance.

Illustrative examples of alkaline metal compounds include sodium hydroxide, potassium hydroxide, sodium nitrate, potassium nitrate, sodium carbonate, potassium carbonate, sodium acetate and potassium acetate. Illustrative examples of alkaline earth metal compounds include magnesium hydroxide, calcium hydroxide, magnesium carbonate and calcium carbonate.

The concentration of alkaline metal compound or alkaline earth metal compound in the composition for forming a protective layer is preferably from 0.001 to 10 parts by mass, and more preferably from 0.01 to 1 part by mass, per 100 parts by mass of the hydrolytic condensate. When the concentration is less than 0.001 part by mass, a sufficient acid resistance improving effect may not be obtained. On the other hand, when the concentration is more than 10 parts by mass, foreign matter may arise during formation of the coating film.

The composition for forming a protective layer may include silica particles in order to enhance the resistance to cracking. When silica particles are included, the concentration of silica particles in the composition for forming a protective layer is preferably from 10 to 60 mass %, and more preferably from 20 to 50 mass %. When the concentration is below 10 mass the crack resistance-enhancing effect may decrease. On the other hand, when the concentration is more than 60 mass %, there is a possibility that the acid resistance will decrease.

### Step C; Separation Trench Forming Step

After the formation of the protective layer 4, as shown in FIG. 1(c), the protective layer 4 is irradiated from above with a laser, thereby forming one or more separation trenches 6 which are deeper than the sum of the thicknesses of the protective layer and the semiconductor layer. The thicknesses here of the above protective layer and the semiconductor layer are the thicknesses at the region irradiated with the laser. Also, the thickness of the semiconductor layer 2 in the region irradiated here with a laser is smaller than the thicknesses of the surrounding semiconductor layers 2 and 3 due to the formation of the recess 5.

The separation trench 6 is a trench having a depth which reaches at least to the substrate. The purpose of the separation trench 6 is to separate the optical semiconductor device into device units. As seen from the top side of the substrate 1, the separation trench 6 is shaped in the form of a grid.

Lasers that may be used in the invention include ArF lasers (wavelength, 213 nm), F2 lasers (wavelength, 157 nm), THG-YAG lasers (wavelength, 355 nm), FHG-YAG lasers (wavelength, 266 nm) and helium-cadmium lasers (wavelength, 325 nm). The intensity of the laser is typically from 0.01 to 100 W, and preferably from 0.1 to 30 W. The laser scanning velocity is usually from 0.01 to 500 mm/s, and preferably from 0.1 to 100 mm/s.

### Step D: Deposit Removing Step

After step C, extraneous matter (such extraneous matter is generally referred to herein as “deposits”) that has formed due to melting, vaporization, chemical reactions and the like at the time of trench formation with a laser and adhered to the optical semiconductor device are removed.

If these deposits are not removed, undesirable electrical shorting paths form between the respective portions (e.g., n electrode layer 2 and p electrode layer 3) making up the optical semiconductor device. The electrical shorting paths may have an adverse influence on the performance of the optical semiconductor device.

An example of a means for removing deposits is washing with an acid. The acid is exemplified by a solution which contains an acidic substance such as sulfuric acid, nitric acid or phosphoric acid, or a mixed solution thereof. The temperature, although not subject to any particular limitation, is typically from 30 to 300° C.

### Step E: Protective Layer Removing Step

After the deposits have been removed, the protective layer 4 is removed as shown in FIG. 1(d).

An example of a means for removing the protective layer 4 is a method which uses an agent for removing a protective layer. Examples of the agents for removing a protective layer include hydrofluoric acid (i.e. aqueous HF solution) and alkali aqueous solutions. Examples of alkali aqueous solutions include aqueous solutions of strong alkalis such as sodium hydroxide or potassium hydroxide. Of these agents for removing a protective layer, the use of hydrofluoric acid (i.e. aqueous HF solution) is especially preferred.

The period of time that the protective layer is brought into contact with the agent for removing a protective layer (e.g., hydrofluoric acid (aqueous HF solution), alkali aqueous solution) is not subject to any particular limitation, provided it is such as to enable the protective layer to be fully removed. The period of time may be, for example, from 0.5 to 10 minutes.

### Step F: Substrate Separating Step

After removal of the protective layer 4, as shown in FIG. 1(g), a separation plane 8 is formed at a deep position on a planar extension of the separation trench 6 at one or more separation trenches 6, and the substrate 1 is separated into device units.

Before separating the substrate 1, as shown in FIG. 1(e), the substrate 1 can be made thinner by polishing. The depth of the separation trench 6 in the substrate 1 is preferably at least one-fifth of the thickness of the substrate 1 at the time of separation.

Also, to facilitate separation, as shown in FIG. 1(f), a back side trench 7 may be formed. The back side trench 7 differs from the separation trench 6 in that it may be shallow, and may be formed, for example, by using a scriber. Alternatively, instead of forming a back side trench 7, the back side of the substrate 1 may be polished until it reaches the separation trench 6.

### EXAMPLES

### Example 1

63.93 g of methyltrimethoxysilane and 186.20 g of tetramethoxysilane were dissolved in 300 g of ethanol within a separable quartz flask. After that, the solution was stirred with a Three-One Motor agitator and the solution temperature was stabilized at 60° C. Next, 150 g of ion-exchanged water and 0.5 g of maleic acid were added, followed by two hours of stirring. After the addition of 1,000 g of a propylene glycol monopropyl ether solution to the reaction solution, the resulting mixture was concentrated to 25% by evaporation to obtain Reaction Solution A. Measurement of the molecular weight of Reaction Solution A by GPC yielded a weight-average molecular weight of 2,100.

Reaction Solution A was applied by spin coating onto a 2-inch GaN-sapphire substrate, thereby giving a film having a thickness of 1 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the polymer film obtained after baking are shown in Table 1.

### Example 2

63.93 g of methyltrimethoxysilane and 186.20 g of tetramethoxysilane were dissolved in 300 g of ethanol within a separable quartz flask. After that, the solution was stirred with a Three-One Motor agitator and the solution temperature was stabilized at 60° C. Next, 150 g of ion-exchanged water and 0.5 g of maleic acid were added, followed by two hours of stirring. After the addition of 1,000 g of a propylene glycol monopropyl ether solution to the reaction solution, the resulting mixture was concentrated to 25% by evaporation, and 0.01 g of sodium acetate was added to the concentrated solution to obtain Reaction Solution B-1. Measurement of the molecular weight of Reaction Solution B-1 by GPC yielded a weight-average molecular weight of 2,200.

20 g of diethoxysilane and 5 g of trichlorosilane were stirred together with 200 g of dibutyl ether in a separable quartz flask, then cooled to 0° C. Next, 20 g of ion-exchanged water was slowly added to this solution, followed by one hour of stirring. 100 g of dibutyl ether and 100 g of ion-exchanged water were then added to the reaction solution. After that, the bottom phase was drawn off by using a separatory funnel. Further, 100 g of ion-exchanged water was added to the top phase, and after that, the bottom phase was drawn off similarly. The top phase was concentrated to 8% by evaporation to obtain Reaction Solution B-2. Measurement of the molecular weight of Reaction Solution B-2 by GPC yielded a weight-average molecular weight of 6,100.

Reaction Solution B-2 was applied by spin coating onto a 2-inch GaN-sapphire substrate, thereby giving a film having a thickness of 0.05 μm. The substrate was heated with a hot plate at 400° C. for 3 minutes in a dry air atmosphere. After cooling, Reaction Solution B-1 was similarly applied by spin coating onto the B-2 film, thereby giving a film composed of Reaction Solution B-1 having a thickness of 1.1 μm. The substrate was heated with a hot plate at 600° C. for 60 minutes in a dry air atmosphere, thereby baking the film. Evaluation results for the coating film (i.e. the polymer film) obtained after baking are shown in Table 1.

### Example 3

59.01 g of vinyltrimethoxysilane and 186.20 g of tetramethoxysilane were dissolved in 300 g of propylene glycol monoethyl ether within a separable quartz flask. After that, the solution was stirred with a Three-One Motor agitator and the solution temperature was stabilized at 60° C. Next, 150 g of ion-exchanged water and 0.5 g of maleic acid were added, followed by two hours of stirring. After the addition of 500 g of a propylene glycol monoethyl ether solution to the reaction solution, the resulting mixture was concentrated to 25% by evaporation, and 0.05 g of a 1% aqueous sodium hydroxide solution was added to the concentrated solution to obtain Reaction Solution C. Measurement of the molecular weight of Reaction Solution C by GPC yielded a weight-average molecular weight of 2,200.

Reaction Solution C was applied by spin coating onto a 2-inch GaN-sapphire substrate, thereby giving a film having a thickness of 0.8 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the coating film (i.e. the polymer film) obtained after baking are shown in Table 1.

### Example 4

90.12 g of phenyltrimethoxysilane and 186.20 g of tetramethoxysilane were dissolved in 300 g of ethanol within a separable quartz flask. After that, the solution was stirred with a Three-One Motor agitator and the solution temperature was stabilized at 60° C. Next, 150 g of ion-exchanged water and 0.5 g of a 1% aqueous nitric acid solution were added, followed by five hours of stirring. After the addition of 1,000 g of a propylene glycol monopropyl ether solution to the reaction solution, the resulting mixture was concentrated to 25% by evaporation, and 0.02 g of potassium acetate was added to the concentrated solution to obtain Reaction Solution D. Measurement of the molecular weight of Reaction Solution D by GPC yielded a weight-average molecular weight of 4,000.

Reaction Solution D was applied by spin coating onto a 2-inch GaN-sapphire substrate, thereby giving a film having a thickness of 1 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the coating film (i.e. the polymer film) obtained after baking are shown in Table 1.

### Example 5

230.50 g of bis(triethoxysilyl)methane and 70.10 g of tetramethoxysilane were dissolved in 500 g of ethanol within a separable quartz flask. After that, the solution was stirred with a Three-One Motor agitator and the solution temperature was stabilized at 60° C. Next, 150 g of ion-exchanged water and 0.5 g of maleic acid were added, followed by one hour of stirring. After the addition of 1,000 g of a propylene glycol monopropyl ether solution to the reaction solution, the resulting mixture was concentrated to 25% by evaporation, and 0.03 g of potassium nitrate was added to the concentrated solution to obtain Reaction Solution E. Measurement of the molecular weight of Reaction Solution E by GPC yielded a weight-average molecular weight of 1,800.

Reaction Solution E was applied by spin coating onto a 2-inch GaN-sapphire substrate, thereby giving a film having a thickness of 1 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the coating film (i.e. the polymer film) obtained after baking are shown in Table 1.

### Example 6

63.93 g of methyltrimethoxysilane and 186.20 g of tetramethoxysilane were dissolved in 300 g of ethanol within a separable quartz flask. After that, the solution was stirred with a Three-One Motor agitator and the solution temperature was stabilized at 60° C. Next, 150 g of ion-exchanged water and 0.5 g of maleic acid were added, followed by two hours of stirring. After the addition of 1,000 g of a propylene glycol monopropyl ether solution to the reaction solution, the resulting mixture was concentrated to 25% by evaporation, and 0.02 g of potassium acetate was added to the concentrated solution to obtain Reaction Solution F. Measurement of the molecular weight of Reaction Solution F by GPC yielded a weight-average molecular weight of 2,200.

Reaction Solution F was applied by spin coating onto a 2-inch GaN-sapphire substrate, thereby giving a film having a thickness of 1 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the coating film (i.e. the polymer film) obtained after baking are shown in Table 1.

### Example 7

50.23 g of dimethoxypolycarbosilane (molecular weight: 2,000) and 47.77 g of methyltrimethoxysilane were dissolved in 300 g of ethanol within a separable quartz flask. After that, the solution was stirred with a Three-One Motor agitator and the solution temperature was stabilized at 60° C. Next, 150 g of ion-exchanged water and 0.5 g of maleic acid were added, followed by two hours of stirring. After the addition of 1,000 g of a propylene glycol monopropyl ether solution to the reaction solution, the resulting mixture was concentrated to 25% by evaporation, and 0.02 g of potassium nitrate was added to the concentrated solution to obtain Reaction Solution G. Measurement of the molecular weight of Reaction Solution G by GPC yielded a weight-average molecular weight of 4,500.

Reaction Solution G was applied by spin coating onto a 2-inch GaN-sapphire substrate, thereby giving a film having a thickness of 1 μm. The substrate was heated with a hot plate at 400° C. for 3 minutes in a dry air atmosphere. In addition, the substrate was heated with a hot plate at 600° C. for 60 minutes in a dry air atmosphere, thereby baking the film. Evaluation results for the coating film (i.e. the polymer film) obtained after baking are shown in Table 1.

### Example 8

Reaction Solution B-2 was applied by spin coating onto a 2-inch GaN-sapphire substrate, thereby giving a film having a thickness of 0.05 μl. The substrate was heated with a hot plate at 400° C. for 3 minutes. After cooling, Reaction Solution B-1 was similarly applied by spin coating onto the B-2 film, thereby giving a film composed of Reaction Solution B-1 having a thickness of 1.1 μm. The substrate was heated with a hot plate at 600° C. for 60 minutes in a dry air atmosphere, thereby baking the film. After baking, grid-like separation trenches were formed at intervals of 1 cm in all directions on the GaN-sapphire substrate using a THG-YAG laser (wavelength: 355 nm) at a power of 15 W and a scanning velocity of 50 mm/s. Evaluation results for this coating film (i.e. polymer film) are shown in Table 1.

### Comparative Example 1

An N-methyl-2-pyrrolidone solution (Reaction Solution H) containing 20 mass % of a polyamic acid (obtained from 9,9-bis(4-aminophenyl)fluorene and 2,2′,3,3′-biphenyltetracarboxylic dianhydride) was applied by spin coating onto a 2-inch GaN-sapphire substrate, thereby giving a film having a thickness of 0.6 μm. The substrate was heated with a hot plate at 200° C. for 3 minutes in a dry air atmosphere. In addition, the substrate was heated with a hot plate at 300° C. for 60 minutes in a dry air atmosphere, thereby baking the film. Evaluation results for the coating film (i.e. polymer film) obtained after baking are shown in Table 1.

### Comparative Example 2

Using a dual-frequency plasma enhanced CVD system manufactured by Youtec Co., Ltd. and using tetraethoxysilane (gas flow rate: 0.3 sccm) as the silica source, a film having a thickness of 0.8 μm was formed on a GaN-sapphire substrate under the conditions that an argon gas flow rate is 100 sccm, RF top showerhead power is 300 W (27.12 MHz), bottom substrate power is 150 W (380 kHz), a substrate temperature is 300° C., and a reaction pressure is 10 torr. Evaluation results for this film are shown in Table 1.

### (Evaluation Tests)

### (1) Acid Resistance

A mixed acid composed of 80 mass % of sulfuric acid and 20 mass % of phosphoric acid was heated to 250° C. A GaN-sapphire substrate on which a protective layer had been formed was then placed in this mixed acid and immersed for 30 minutes. After that, the substrate was examined by scanning electron microscopy (SEM). In addition, after such immersion, the substrate was additionally immersed in a 10% aqueous solution of hydrofluoric acid for 5 minutes, thereby removing the protective layer. The substrate was then again examined by SEM.

(1-1) State of GaN Layer after Immersion in Mixed Acid

The state of the GaN layer after removal of the protective layer was examined by SEM. Cases in which erosion into the GaN layer was not observed were rated as “Good,” cases in which part of the GaN layer was eroded were rated as “Fair,” and cases in which the GaN layer was completely eroded were rated as “NG.”

### (1-2) Decrease Rate in Thickness of Protective Layer After Immersion in Mixed Acid

The thickness of the protective layer before and after immersion in the mixed acid was evaluated by comparatively examining cross-sections of the protective layer by SEM. Cases in which the decrease rate in the thickness of the protective layer was less than 30% were rated as “Good,” cases in which the decrease rate was at least 30% but less than 90% were rated as “Fair,” and cases in which the decrease rate was at least 90% were rated as “NG.”

### (1-3) Surface State of Protective Layer After Immersion in Mixed Acid

The film surface after immersion in mixed acid was examined by SEM. Cases in which foreign matter on the film surface, film delamination and other defects were not observed were rated as “Good.” Cases in which foreign matter on the film surface, film delamination or other defects were observed were rated as “Fair.”

### (2) Electrical Characteristics

The forward voltage V_{F} (25° C.; I_{F}, 20 mA) on GaN after removal of the protective layer was measured. When the forward voltage was in a range of 2 to 5 V, the electrical characteristics were rated as “Good.” When the forward voltage was a value outside of this range, the electrical characteristics were rated as “NG.”

TABLE 1

| | Acid Resistance | | | |
|---|---|---|---|---|
| | | Decrease rate | | |
| | State of GaN | in thickness of | Surface state of | |
| | layer after | protective layer | protective layer | Electrical |
| | immersion in | after immersion | after immersion | charac- |
| | mixed acid | in mixed acid | in mixed acid | teristics |
| Example 1 | good | fair | fair | good |
| Example 2 | good | good | good | good |
| Example 3 | good | good | good | good |
| Example 4 | good | good | good | good |
| Example 5 | good | good | good | good |
| Example 6 | good | good | good | good |
| Example 7 | good | good | good | good |
| Example 8 | good | good | good | good |
| Comp. | NG | NG | — | NG |
| Ex. 1 | | | | |
| Comp. | fair | fair | fair | NG |
| Ex. 2 | | | | |

In Examples 1 to 8, because the polymer films obtained all had a sufficient acid resistance, erosion of the GaN layer due to the mixed acid did not arise and the electrical characteristics were at a satisfactory level. In particular, in those cases where an alkaline metal was added (i.e. Examples 2 to 8), the decrease rate in the thickness of the protective layer was small, the surface of the protective layer was free of foreign matter and the like, and the acid resistance was better than in Example 1. Moreover, as shown in Example 8, even in the film after laser treatment, a cross-section of the treated film showed no signs of erosion by acid, film defects and the like.

On the other hand, in Comparative Example 1, the acid resistance was inadequate and the protective layer disappeared completely with acid immersion. As a result of that, GaN erosion arose. In Comparative Example 2 as well, the acid resistance was inadequate. As a result of that, the protective layer and GaN were eroded by the mixed acid.

1. A method for manufacturing an optical semiconductor device having a substrate and a semiconductor layer formed on the substrate, wherein the method comprises:
a protective layer forming step of forming a protective layer by coating a surface of the semiconductor layer formed on the substrate with a composition for forming a protective layer;
a separation trench forming step of forming one or more separation trenches that are deeper than a sum of a thickness of the protective layer and a thickness of the semiconductor layer by irradiating the protective layer from above with a laser; and
a deposit removing step of removing deposits that arise during formation of the separation trenches, and
wherein the composition for forming a protective layer includes a siloxane polymer and an organic solvent.

2. The method for manufacturing an optical semiconductor device according to claim 1, further comprising a protective layer removing step of removing the protective layer after the deposit removing step.

3. The method for manufacturing an optical semiconductor device according to claim 1, further comprising, as a final step, a substrate separating step of separating the substrate into device units at the one or more separation trenches.

4. The method for manufacturing an optical semiconductor device according to claim 1, further comprising, prior to the protective layer forming step, a recess forming step of forming a recess which has a broader width than that of the separation trench and is shallower than the separation trenches in a region of the semiconductor layer that includes a position where the separation trenches are to be formed.

5. The method for manufacturing an optical semiconductor device according to claim 1,
wherein the siloxane polymer is a hydrolytic condensate obtained by hydrolytic condensation of a silane compound containing at least one type selected from the group consisting of:
compounds represented by general formula (1) below
R¹_{c}SiX¹_{4-c} (1),
wherein R¹ is a monovalent non-hydrolyzable group, X¹ is a monovalent hydrolyzable group, and the letter c is an integer from 0 to 2;
compounds represented by general formula (2) below
R²_{b}(X²)_{3-b}Si—R⁴—Si(X³)_{3-C}R³_{c} (2),
wherein R² and R³ are the same or different and each is independently a monovalent non-hydrolyzable group, R⁴ is a divalent non-hydrolyzable group, X² and X³ are the same or different and each is independently a monovalent hydrolyzable group, and the letters b and c are the same or different and each is independently an integer from 0 to 2; and
hydrolyzable polycarbosilanes.

6. The method for manufacturing an optical semiconductor device according to claim 1,
wherein the siloxane polymer has a weight-average molecular weight of from 1,000 to 30,000.

7. The method for manufacturing an optical semiconductor device according to claim 1,
wherein the composition for forming a protective layer includes from 0.001 to 10 parts by mass of an alkaline metal compound or an alkaline earth metal compound per 100 parts by mass of the siloxane polymer.

8. The method for manufacturing an optical semiconductor device according to claim 1, wherein the composition for forming a protective layer includes silica particles.

9. A composition for forming a protective layer of an optical semiconductor device for forming a protective layer formed temporarily on a surface of a semiconductor layer in the course of optical semiconductor device fabrication, wherein the composition includes a siloxane compound and an organic solvent.

10. The composition for forming a protective layer of an optical semiconductor device according to claim 9,
wherein the siloxane polymer is a hydrolytic condensate obtained by hydrolytic condensation of a silane compound containing at least one type selected from the group consisting of:
compounds represented by general formula (1) below
R¹_{c}SiX¹_{4-c} (1),
wherein R¹ is a monovalent non-hydrolyzable group, X¹ is a monovalent hydrolyzable group, and the letter c is an integer from 0 to 2;
compounds represented by general formula (2) below
R²_{b}(X²)_{3-b}Si—R⁴—Si(X³)_{3-c}R³_{C} (2),
wherein R² and R³ are the same or different and each is independently a monovalent non-hydrolyzable group, R⁴ is a divalent non-hydrolyzable group, X² and X³ are the same or different and each is independently a monovalent hydrolyzable group, and the letters b and c are the same or different and each is independently an integer from 0 to 2; and
hydrolyzable polycarbosilanes.
